(19) United States
(12) Patent Application Publication
(10) Pub. No.: US 2014/0160701 A1
(43) Pub. Date: Jun. 12, 2014

(54) RISER CARD ASSEMBLY

(71) Applicants: HON HAI PRECISION INDUSTRY CO., LTD., New Taipei (TW); HONG FU JIN PRECISION INDUCTRY (ShenZhen) CO.,LTD., Shenzhen (CN)

(72) Inventors: YU-WEI HE, Shenzhen (CN); XIU-QUAN HU, Shenzhen (CN)

(73) Assignees: HON HAI PRECISION INDUSTRY CO., LTD., New Taipei (TW); HONG FU JIN PRECISION INDUCTRY (ShenZhen) CO.,LTD., Shenzhen (CN)

(21) Appl. No.: 14/018,722

(22) Filed: Sep. 5, 2013

(30) Foreign Application Priority Data
Dec. 12, 2012 (CN) 2012105334565

(51) Int. Cl. H05K 5/02

(52) U.S. Cl. CPC H05K 5/0217
USPC 361/756; 361/752

(57) ABSTRACT

A riser card assembly includes a chassis, a tray, and a riser card. The tray is located in the chassis. The tray includes a bottom plate and a protecting board extending from the bottom plate. The riser card includes an edge connector. The riser card is located on the tray and substantially parallel to the bottom plate. The protecting board is substantially flushed with the edge connector to prevent the edge connector from interference.

### CROSS-REFERENCE TO RELATED APPLICATIONS

This application claims all benefits accruing under 35 U.S.C. §119 from China Patent Application No. 201210533456.5, filed on Dec. 12, 2012, in the China Intellectual Property Office, the contents of which are hereby incorporated by reference. Relevant subject matter is disclosed in co-pending U.S. Patent Applications entitled “RISER CARD ASSEMBLY,” Attorney Docket Number US48644, U.S. application Ser. No. ______, filed on ______.

### BACKGROUND

1. Technical Field

The present disclosure relates to riser card assemblies, and particular to an riser card assembly with a riser card.

2. Description of Related Art

In order to increase a number of expansion cards with different types of connectors to a motherboard of a computer, a riser card with a uniform output connector is provided to electronically connect the plurality of expansion cards to the motherboard. The riser card includes a printed circuit board, and a plurality of connectors located on outer edges of the printed circuit board to receive the expansion cards. However, the riser card is used alone, and a connector on outer edge of the riser card may interfere with other electronic components and cause damage after frequent use. Therefore, there is room for improvement within the art.

### BRIEF DESCRIPTION OF THE DRAWINGS

FIG. 1 is an exploded, isometric, cutaway view of one embodiment of a riser card assembly.

FIG. 2 is similar to FIG. 1, but shown from another aspect.

FIG. 3 is an isometric cutaway view of a chassis and a bracket of FIG. 1.

FIG. 4 is an assembled view of the riser card assembly of FIG. 1, but shown from another aspect.

FIG. 5 is similar to FIG. 4, but shown from another aspect.

FIG. 6 is a front view of the riser card assembly of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

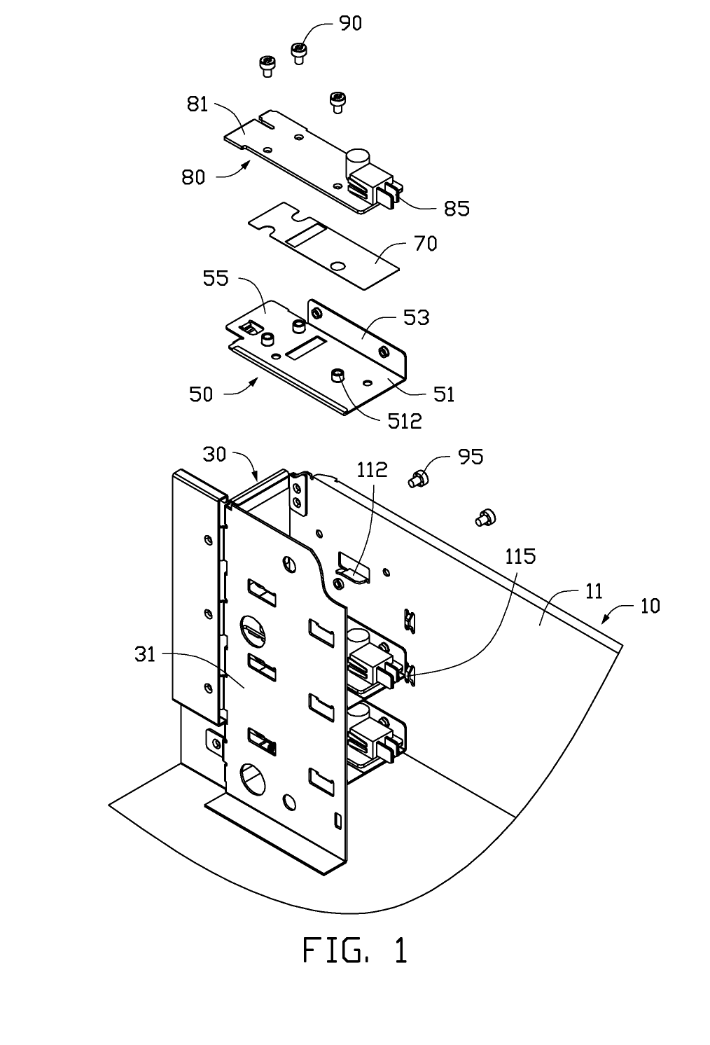

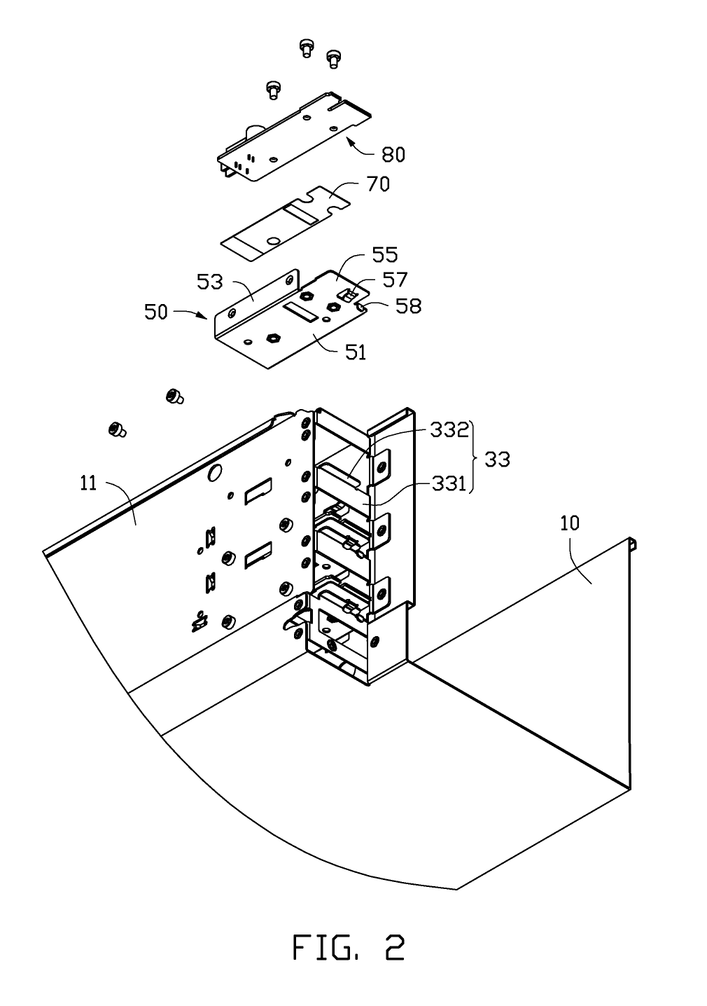

FIG. 1 and FIG. 2 illustrate one embodiment of a riser card assembly. The riser card assembly includes a chassis 10, a bracket 30 mounted to the chassis 10, a tray 50, a riser card 80. An insulating sheet 70 may be located between the riser card 80 and the tray 50.

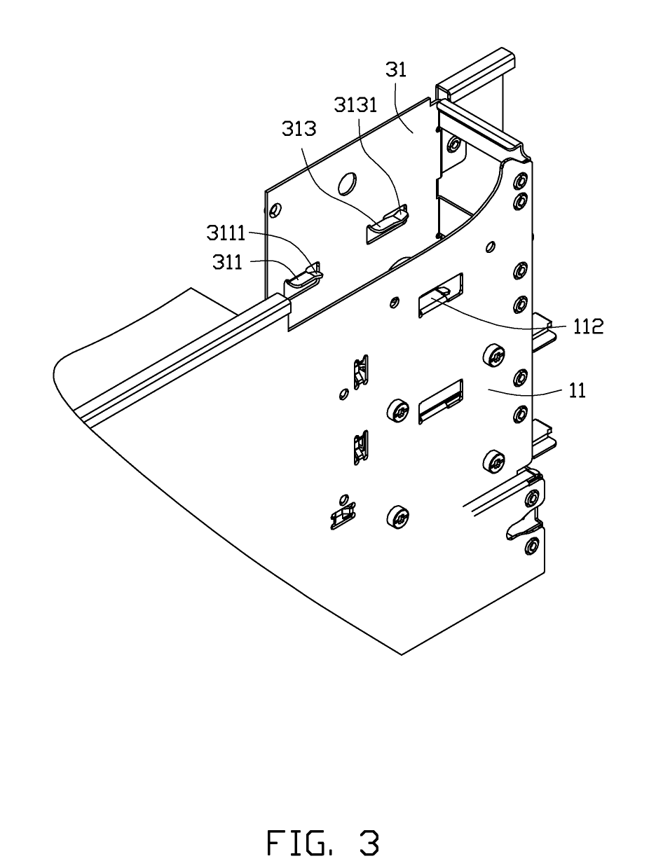

FIG. 3 illustrates the chassis 10 and the bracket 30. The chassis 10 includes a side wall 11. A plurality of first supporting tabs 112 and a plurality of bridges 115 are located on the side wall 11.

The bracket 30 includes a side panel 31 and a plurality of front panels 33.

The side panel 31 is substantially parallel to the side wall 11. A plurality of second supporting tabs 311 and a plurality of guiding tabs 313 are located on the side panel 31. Each second supporting tab 311 includes a downwardly slanted guiding portion 3111. Each guiding tab 313 includes an upwardly slanted guiding portion 3131. Each front panel 33 includes a front board 331 and an extending tab 332. The front board 331 is substantially perpendicular to the side panel 31. The extending tab 332 is substantially perpendicular to the front board 331.

The tray 50 includes a bottom plate 51, a protecting board 55, and a fixing plate 53. The protecting board 55 extends from the bottom plate 51. The protecting board 55 and the bottom plate 51 are substantially located on a same plane. The fixing plate 53 is substantially perpendicular to the bottom plate 51. A hook 57 and a stop tab 58 extend down from the bottom plate 51. A cross section of the hook 57 is substantially L-shaped. Three posts 512 protrude from the bottom plate 51.

The riser card 80 includes an edge connector 81 and a plug 85 located on opposite side of the edge connector 81.

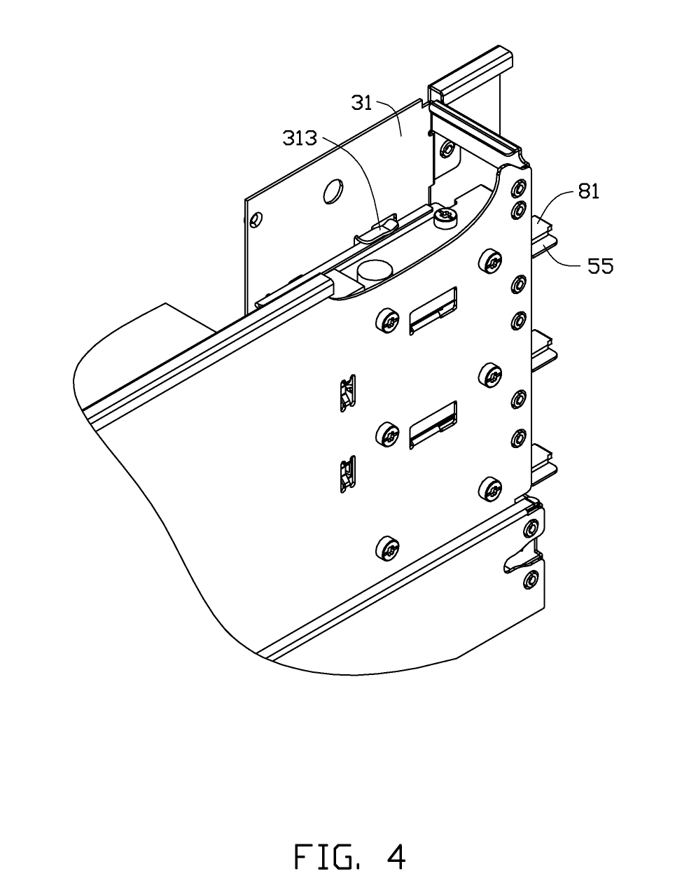

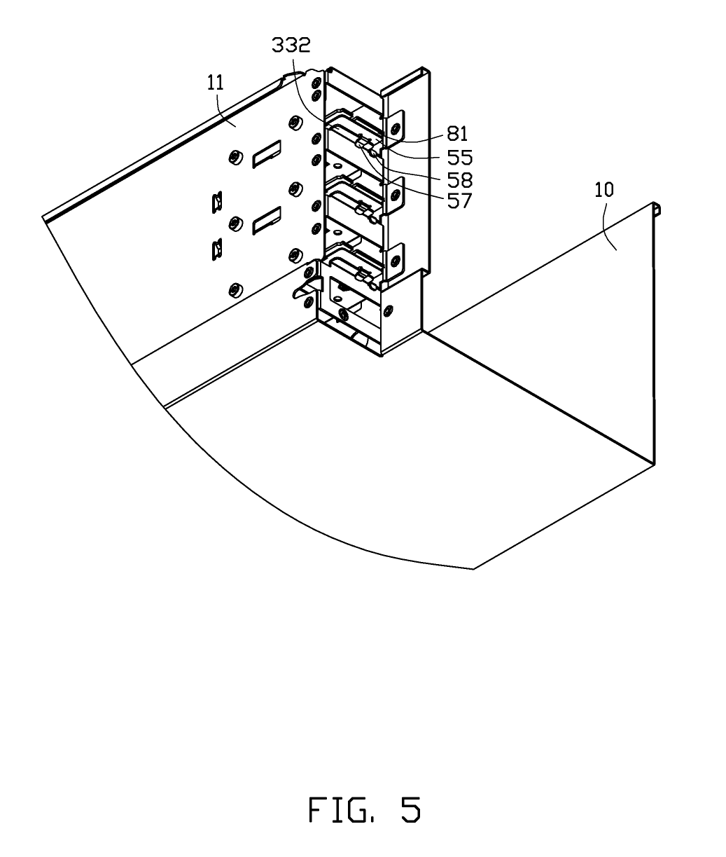

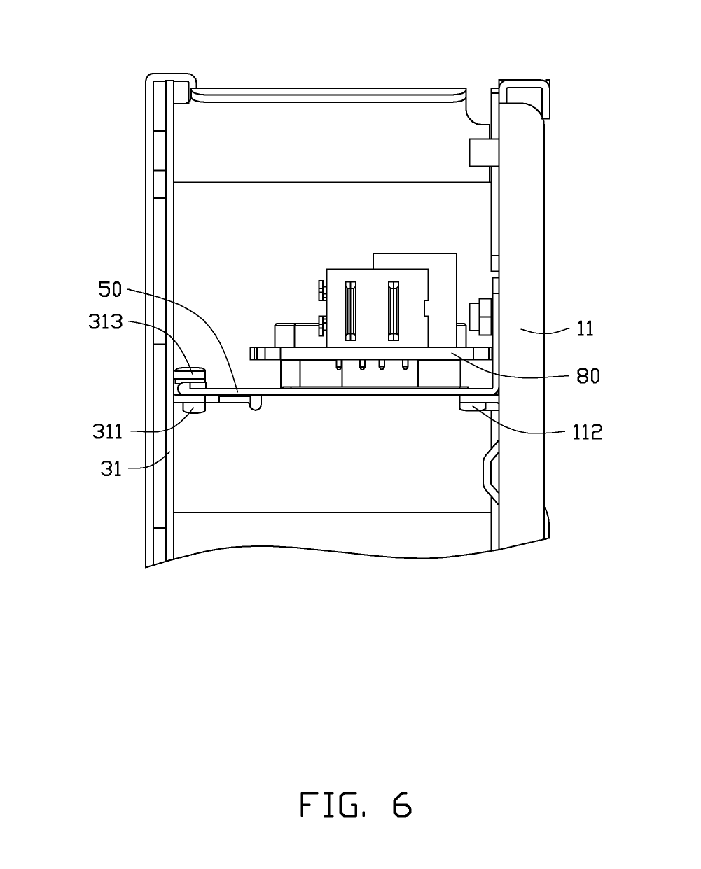

FIG. 4 to FIG. 6 illustrates an assembled view of the riser card assembly. In assembly, the insulating sheet 70 is located on the tray 50. The riser card 80 is fixed to the three posts 512 through three fasteners 90. The riser card 80 and bottom plate 51 are spaced by the three posts 512. The protecting board 55 is substantially flushed with the edge connecter 81 to prevent the edge connecter 81 from interference. The tray 50 and the riser card 80 are positioned in front of the bracket 30. The tray 50 and the riser card 80 are moved into the bracket 30 along a direction substantially parallel to the side panel 31. The tray 50 is guided by the upwardly slanted guiding portion 3131 and the downwardly slanted guiding portion 3111. The tray 50 is slid on the first supporting tab 112 and the second supporting tab 311. The first supporting tab 112 and the second supporting tab 311 support the tray 50. The second supporting tab 311 and the guiding tab 313 abut on opposite sides of the bottom plate 51 of the tray 50. When the tray 50 is received in the bracket 30, the hook 57 of the tray 50 is engaged with the extending tab 332 of the front panel 33 to restrict further movement of the tray 50, and the tray 50 is blocked by the bridge 115. The fixing plate 53 is then fixed to the side wall by rivets. The tray 50 and the riser card 80 are mounted to the chassis 10 and the bracket 30.

In other embodiments, to protect the edge connector 81, the edge connector 81 should not exceed the protecting board 55 of the tray 50.

It is to be understood, however, that even though numerous characteristics and advantages have been set forth in the foregoing description of preferred embodiments, together with details of the structures and functions of the preferred embodiments, the disclosure is illustrative only, and changes may be made in detail, especially in the matters of shape, size, and arrangement of parts within the principles of the invention to the full extent indicated by the broad general meaning of the terms in which the appended claims are expressed.

What is claimed is:

1. A riser card assembly comprising:
a chassis;
a tray, located in the chassis, the tray comprising a bottom plate and a protecting board extending from the bottom plate; and
a riser card, comprising an edge connector, the riser card located on the tray and substantially parallel to the bottom plate, and the protecting board being substantially flushed with the edge connector.

2. The riser card assembly of claim 1, wherein a plurality of posts protrudes from the bottom plate, the riser card is fixed to the plurality of posts, and the riser card and the bottom plate are spaced by the plurality of posts.

3. The riser card assembly of claim 1, wherein an insulating sheet is located between the riser card and the bottom plate of the tray.

4. The riser card assembly of claim 1, wherein the chassis comprising a side wall and a bracket, the bracket comprising a side panel, the side panel is substantially parallel to the side wall, a first supporting tab is located on the side wall, a second supporting tab is located on the side panel, and the tray is supported by the first supporting tab and the second supporting tab.

5. The riser card assembly of claim 4, wherein a guiding tab is located on the side panel, and the guiding tab and the first supporting tab abut on opposite sides of the tray.

6. The riser card assembly of claim 4, wherein the bracket further comprises a front panel, and the bottom plate of the tray is engaged with the front panel.

7. The riser card assembly of claim 6, wherein the front panel comprises a front board and an extending tab, the front board is substantially perpendicular to the side panel, the extending tab is substantially perpendicular to the front board, a hook is located on the bottom plate of the tray, and the hook is engaged with the extending tab to retain the tray to the bracket.

8. The riser card assembly of claim 7, wherein a cross sectional view of the hook is substantially L-shaped.

9. The riser card assembly of claim 4, wherein the tray further comprises a fixing plate, the fixing plate is substantially perpendicular to the bottom plate, and the fixing plate is fixed to the side wall.

10. The riser card assembly of claim 4, wherein the protecting board and the edge connecter are located on an outer side of the bracket.

11. A riser card assembly comprising:
a chassis;
a tray, located in the chassis, the tray comprising a bottom plate and a protecting board extending from the bottom plate; and
a riser card, comprising an edge connector, the riser card located on the tray and being substantially parallel to the bottom plate, and the edge connector not exceed the protecting board.

12. The riser card assembly of claim 11, wherein a plurality of posts protrudes from the bottom plate, the riser card is fixed on the plurality of posts, and the riser card and the bottom plate are spaced by the plurality of posts.

13. The riser card assembly of claim 11, wherein an insulating sheet is located between the riser card and the bottom plate of the tray.

14. The riser card assembly of claim 11, wherein the chassis comprising a side wall and a bracket, the bracket comprising a side panel, the side panel is substantially parallel to the side wall, a first supporting tab is located on the side wall, a second supporting tab is located on the side panel, and the tray is supported by the first supporting tab and the second supporting tab.

15. The riser card assembly of claim 14, wherein a guiding tab is located on the side panel, and the guiding tab and the first supporting tab abut on opposite sides of the tray.

16. The riser card assembly of claim 14, wherein the bracket further comprises a front panel, and the bottom plate of the tray is engaged with the front panel.

17. The riser card assembly of claim 16, wherein the front panel comprises a front board and an extending tab, the front board is substantially perpendicular to the side panel, the extending tab is substantially perpendicular to the front board, a hook is located on the bottom plate of the tray, and the hook is engaged with the extending tab to retain the tray to the bracket.

18. The riser card assembly of claim 17, wherein a cross sectional view of the hook is substantially L-shaped.

19. The riser card assembly of claim 14, wherein the tray further comprises a fixing plate, the fixing plate is substantially perpendicular to the bottom plate, and the fixing plate is fixed to the side wall.

20. The riser card assembly of claim 14, wherein the protecting board and the edge connecter are located on an outer side of the bracket.
